(19) United States
(12) Patent Application Publication
(10) Pub. No.: US 2002/0013138 A1
(43) Pub. Date: Jan. 31, 2002

(54) RADIO RECEIVER

(76) Inventors: MARCUS BENTHIN, HILDESHEIM (DE); HERBERT THEIS, DIEKHOLZEN (DE)

Correspondence Address: STRIKER STRIKER & STENBY, 103 EAST NECK ROAD, HUNTINGTON, NY, 11743

(21) Appl. No.: 09/284,556

(22) PCT Filed: Oct. 16, 1997
(86) PCT No.: PCT/DE97/02377

(30) Foreign Application Priority Data
Oct. 21, 1996 (DE) 19643282.0

(51) Int. Cl. H04B 1/06; H05K 11/00; H05K 11/02; H04B 1/08

(52) U.S. Cl. 455/346; 455/345; 455/344; 455/348

(57) ABSTRACT

A radio receiver (1), preferably a car radio, is proposed which is protected against theft and is used for mobile phone calls. To that end, the radio receiver (1) has a removable control panel (5) for operating the radio receiver (1), wherein the control panel (5) has a keypad (10). The control panel (5) has a radio device (50), preferably embodied as a radio telephone for communication with at least one radio station. Furthermore, at least one interface (15) is provided, by way of which, when the control panel (5) is connected to the radio receiver (1), data and/or antenna signals can be exchanged between the control panel (5) and the radio receiver (1). The radio device (50) can be operated using the keypad (10).

### PRIOR ART

The invention is based on a radio receiver as generically defined by the preamble to the main claim.

Radio receivers embodied as a car radio are already known in which the control panel is embodied as a removable part of the front cap. On leaving the vehicle, one can easily remove the control panel from the car radio and take it along. Without the control panel, the radio receiver is not functional. This makes anti-theft protection of the radio receiver possible.

A car radio with a removable control panel is known for instance from “Fascination made by GRUNDIG, GRUNDIG Revue '92”, under the model name 2680 VD.

Advantages of the Invention

The radio receiver of the invention having the characteristics of the main claim has the advantage over the prior art that the functional versatility of the control panel is increased substantially by embodying the control panel as a radio device or radio telephone. Operating the radio receiver and the radio device with the same control panel also reduces the expense for material, the space needed, and the production costs, and makes for a clear, convenient link between radio receiver and radio device operation.

By connecting the radio device to the radio receiver, the advantage is also obtained that data and/or antenna signals can be exchanged between the control panel and the radio receiver. In this way, on the one hand the radio device is utilized as a control panel for the radio receiver, and on the other the radio receiver is used for the radio mode. Thus the functional versatility of the radio receiver is also increased.

By the provisions recited in the dependent claims, advantageous refinements of and improvements to the radio receiver defined by the main claim are possible.

It is advantageous to equip the control panel with a battery that can be charged via the interface. In this way, the control panel remains functional even after removal from the radio receiver, because after removal it can then be supplied with current from the battery.

It is also advantageous to equip the control panel with a card chute for receiving an access authorization card. As a result, with a single access authorization card and a single card chute, both the radio receiver and the radio device can be put into operation. This saves space, effort, material and expense in production and at the same time increases the clarity and convenience of operating the radio device or the radio receiver.

Embodying the interface at least in part as an optical interface, preferably acting in the infrared range, is especially advantageous. In this way, above all in the data exchange between the control panel and the radio receiver with relatively high data rates, electromagnetic compatibility problems on overcoupling of signals between individual connecting lines of the interface are prevented from occurring.

Another advantage is that the control panel includes an earpiece and/or a microphone, and that when the control panel is removed, radio signals for communication with the radio station can be sent from and/or received by the control panel via a preferably retractable antenna. In this way, the control panel can also be used independently of the radio receiver as a radio device for communication with radio stations. This makes mobile, location-independent communication possible. If the radio receiver is embodied as a car radio, the advantage is additionally obtained that the taking the control panel along to prevent theft is not a nuisance to the user, since the control panel, when separated from the car radio, is simultaneously useful because it is equipped with the functionality of a mobile telephone. The user is thus given the capability of making mobile phone calls outside his vehicle while at the same time achieving theft protection for his car radio.

It is advantageous that when the control panel is mounted on the radio receiver, the antenna and/or the earpiece and/or the microphone is turned off, and that the radio receiver is connected to an audio playback unit and/or a hands-free device. In this way, the functional versatility of the radio receiver is increased, since its audio playback unit and/or its hands-free device can also be utilized by the radio device. This also simplifies operation of the radio device, especially in speech input via the hands-free device, and provides an opportunity of listening in via the audio playback unit.

It is also advantageous to use a display on the control panel to show information about commands selected at the keypad and/or about data received in the interface. In this way, only a single display is needed for both the radio device and the radio receiver, thus saving space, effort, material, and cost in production. Moreover, by the use of a single display, a high degree of simplicity and convenience of use for the user are made possible.

### DRAWING

An exemplary embodiment of the invention is shown in the drawing and described in further detail in the ensuing description.

FIG. 1 shows a front view of the control panel;

FIG. 2 shows a back view of the control panel;

FIG. 3 shows a front view of the radio receiver with the control panel removed; and

FIG. 4 is a block circuit diagram of the radio receiver with the control panel connected to it.

### DESCRIPTION OF THE EXEMPLARY EMBODIMENT

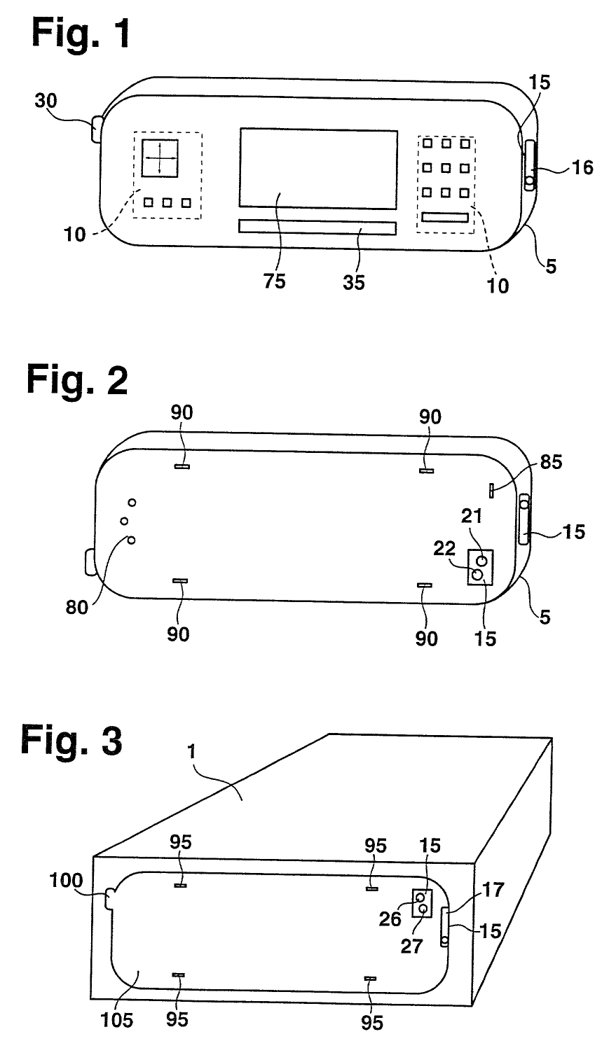

In FIG. 1, the front view of a control panel 5 of a radio receiver 1, embodied as a car radio, is shown. To provide theft protection, the control panel 5 is removable from the radio receiver 1. It has a keypad 10 for operating the radio receiver 1. A display 75 and a card chute 35 for receiving an access authorization card are also provided. An interface 15 with electrical contacts, embodied as a bush 16, is provided on a side wall of the control panel 5 and makes the electrical connection between the control panel 5 and the radio receiver 1 when the control panel 5 is mounted on the radio receiver 1 or in other words is connected to the radio receiver 1. The control panel 5 has a retractable antenna 30 on a further side wall. A radio device 50 embodied as a radio telephone is integrated with the control panel 5.

On its back side, the control panel 5 in FIG. 2 has recesses 80 for an earpiece 40 and a recess 85 for a microphone 45. There are also four recesses 90 on the backside of the control panel 5 for a retaining mechanism of the radio receiver 1, for retaining the control panel 5 on the radio receiver 1. An infrared transceiver 21, 22 is also provided on the back side of the control panel 5. The infrared transceiver 21, 22 has a transmitter 21 and a receiver 22 and is part of the interface 15.

FIG. 3 shows the front view of the radio receiver 1. Four retaining tabs 95 engage the recesses 90 of the control panel 5 when the control panel 5 is mounted on the radio receiver 1, so that the control panel 5 is connected solidly to the radio receiver 1 and is secured against falling out and against a loss of contact. The retaining tabs 95 are disposed in an opening 105 of the radio receiver 1 for receiving the control panel 5. The opening 105 has a recess 100 for receiving the retracted antenna 30 of the control panel 5. On a side wall of the opening 105, a bush 17 of the interface 15 that corresponds with the bush 16 of the control panel 5 is also provided. An infrared transceiver 26, 27 is also accommodated in the opening 105; it has a transmitter 26 and a receiver 27. When the control panel 5 has been placed in the opening 105, the transmitter 26 of the radio receiver 1 corresponds with the receiver 22 of the control panel 5, and the transmitter 21 of the control panel 5 corresponds then with the receiver 21 of the radio receiver 1. Thus the infrared transceiver 26, 27 of the radio receiver 1 is also part of the interface 15.

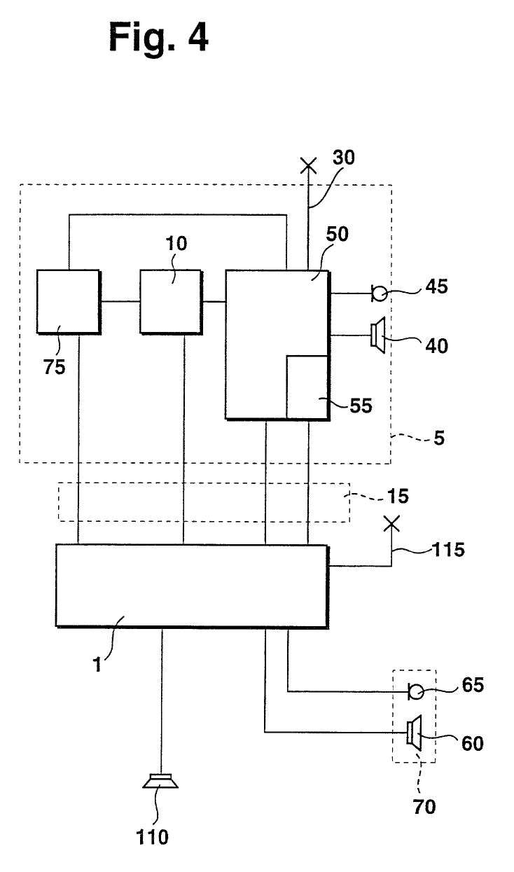

In FIG. 4, the block circuit diagram of the radio receiver upon connection with the control panel 5 is shown.

The radio device 50 has a battery 55 and is connected to the microphone 45 and the earpiece 40 and to the antenna 30. Also connected to the radio device 50 are the keypad 10 and the display 75. The keypad 10 and the display 75 are also connected to one another. The display 75, keypad 10, radio device 50, and battery 55 are all connected to the radio receiver 1 via the interface 15. A handset 70 with a mouthpiece 65 and an audio playback unit 60 is connected to the radio receiver 1. Also connected to the radio receiver 1 are a further audio playback unit 110 and a transceiver antenna 115.

For the case where the control panel 5 is inserted into the opening 105 of the radio receiver 1, the connection contacts of the bush 16 of the control panel 5 are electrically conductively connected to corresponding counterpart contacts of the bush 17 of the radio receiver 1. The transmitter 21 of the control panel 5 and the receiver 27 of the radio receiver 1, and the transmitter 26 of the radio receiver 1 and the receiver 22 of the control panel 5, are in close mechanical and optical contact with one another. Via the electrical contacts of the bushes 16 and 17, the control panel 5 is supplied with current, the battery 55 is charged, and antenna signals generated by the radio device 50 are sent on to the radio receiver 1 for broadcasting via its transceiver antenna 115, or antenna signals received from the radio receiver 1 are output to the radio device 50 via the transceiver antenna 115 of the radio receiver.

The data communication between the control panel 5 and the radio receiver 1 for forwarding messages and signalling data to the display 75 or for sending inputs at the keypad 10 to the radio receiver 1 can also be done via the electrical connection contacts of the bushes 16 and 17. When the data rate is high, however, the danger exists that overcoupling of signals of the individual connecting lines will occur, causing problems with electromagnetic compatibility. In that case, the data communication should advantageously be done via the infrared transceivers 21, 22 and 26, 27. It is also conceivable for the antenna signals to be transmitted via the infrared transceivers 21, 22 and 26, 27. Both the radio device 50 and the radio receiver 1 can be operated via the keypad 10. Information about the inputs or commands selected at the keypad 10 can be shown on the display 75. For instance, a frequency set for the radio receiver mode, or a selected reception range, can be displayed. In the mobile phone mode, a telephone number entered at the keypad 10 or a speed dialed destination input at the keypad 10 can be displayed. It is equally possible for data received from the radio receiver 1 in te interface 15 to be shown on the display 75, examples being information on the receiving field intensity for the radio reception mode, and the telephone number of a caller for the mobile phone mode. Once the control panel 5 is mounted on the radio receiver 1, the built-in antenna 30, the earpiece 40 and the microphone 45 of the control panel 5 are turned off. The corresponding functions are then taken over by the permanently built-in radio receiver 1. The antenna signals generated by the radio device 50 are forwarded via the interface 15 and the radio receiver 1, optionally via an antenna amplifier, not shown, to the transceiver antenna 115 for broadcasting. In this way, radio signals from the control panel 5 can be broadcast via the transceiver antenna 115 to at least one radio station of a radio network, such as a mobile telephone network. Conversely, radio signals broadcast by radio stations of the radio network can be received by the transceiver antenna 115 of the radio receiver 1 and carried on to the radio device 50 via the radio receiver 1 and the interface 15. An acoustical playback of such radio signals can be done via the audio playback unit 60 of the handset 70 and/or the further audio playback unit 110. Via the mouthpiece 65 of the handset 70, audio and/or speech signals can be input by the user at the radio receiver 1. Instead of the mouthpiece 65 of the handset 70, a separate mouthpiece can be connected to the radio receiver 1 that performs the same purpose. The audio and/or speech signals input are then carried on from the radio receiver 1 via the interface 15 to the radio device 50 to generate corresponding antenna signals. The antenna signals are then passed on in a manner described to the transceiver antenna 115 for broadcasting. The transceiver antenna 115 is embodied as a combination antenna and also serves to receive radio signals. By inserting an access authorization card into the card chute 35, the function of the radio device 50, which is integrated with the control panel 5, and the function of the radio receiver 1 can be activated. In this way, unauthorized use of the radio device 50 or of the radio receiver 1 is prevented.

If the user of the radio receiver 1 leaves his vehicle, then he takes out the control panel 5 to secure the radio receiver 1 against theft. At the same time, the antenna 30, earpiece 40 and microphone 45 are activated. To improve the transmission and reception properties, the use can pull out the antenna 30 and thus lengthen it. The control panel 5 can now be used as a fully functional mobile phone, independently of the radio receiver 1, for communication with radio stations of the radio network. To that end, the access authorization card remains in the control panel, whose card chute 35 includes a card reader. The supply of current is then effected by the battery 55. Inputs at the keypad 10 can be shown as described on the display 75 for the mobile phone mode. Radio signals received by the antenna 30 can also be displayed on the display 75, after conversion into corresponding data in the radio device 50. Such data may be for instance the telephone number of a caller. The communication with radio stations of the radio network is now effected in that radio signals generated by the radio device 50 are broadcast directly from the antenna 30, or radio signals from the radio device 50 are received directly via the antenna 30. Removal of the control panel 5 from the radio receiver 1 makes the radio receiver 1 no longer operable and thus no longer functional.

Since normally the name or type of the radio receiver is shown on the control panel 5, it is also no longer possible, when the control panel 5 has been removed, to guess what the price class of the radio receiver is. This provides extremely effective antitheft protection, while at the same time the user is given a fully functional mobile phone to use.

The invention is not limited to car radios but instead can be employed for arbitrary radio receivers.

1. A radio receiver (1), preferably a car radio, with a removable control panel (5) for operating the radio receiver (1), wherein the control panel (5) has a keypad (10), characterized in that the control panel (5) has a radio device (50), preferably embodied as a radio telephone for communication with at least one radio station, that at least one interface (15) is provided, by way of which, when the control panel (5) is connected to the radio receiver (1), data and/or antenna signals can be exchanged between the control panel (5) and the radio receiver (1), and that the radio device (50) can be operated using the keypad (10).

2. The radio receiver (1) of claim 1, characterized in that when the control panel (5) is connected to the radio receiver (1), a supply of current to the control panel (5) is effected via the interface (15).

3. The radio receiver (1) of claim 1 or 2, characterized in that the control panel (5) includes a battery (55), which can be charged via the interface (15).

4. The radio receiver (1) of claim 1, 2 or 3, characterized in that the control panel (5) includes a card slot (35) for receiving an access authorization card.

5. The radio receiver (1) of one of the foregoing claims, characterized in that the interface (15) is embodied at least in part as an optical interface, preferably operating in the infrared range, with one transceiver (21, 22) on the control panel (5) and one transceiver (26, 27) on the radio receiver.

6. The radio receiver (1) of one of the foregoing claims, characterized in that the control panel (5) includes an earpiece (40) and/or a microphone (45).

7. The radio receiver (1) of one of the foregoing claims, characterized in that when the control panel (5) is removed, radio signals for communication with the radio station can be sent from and/or received by the control panel (5) via a preferably retractable antenna (30).

8. The radio receiver (1) of one of claims 6 or 7, characterized in that when the control panel (5) is mounted on the radio receiver (1), the antenna (30) and/or the earpiece (40) and/or the microphone (45) is turned off.

9. The radio receiver (1) of one of the foregoing claims, characterized in that the radio receiver (1) is connected to an audio playback unit (60) and/or a mouthpiece (65), preferably of a handset (70).

10. The radio receiver (1) of one of the foregoing claims, characterized in that a display of information about the commands selected at the keypad (10) and/or of data received in an interface (15) is effected on a display (75) of the control panel (5).
